(19) United States
(12) Patent Application Publication
(10) Pub. No.: US 2026/0324066 A1
(43) Pub. Date: Oct. 15, 2026

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Kuan-Ting PAN, Hsinchu (TW); Jia-Chuan YOU, Hsinchu (TW); Chia-Hao CHANG, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 19/179,259

(22) Filed: Apr. 15, 2025

(51) Int. Cl. H10D 84/85; H10D 84/01; H10D 84/83

(52) U.S. Cl. CPC H10D 84/852; H10D 84/0167; H10D 84/0177; H10D 84/0188; H10D 84/83135

(57) ABSTRACT

A semiconductor device includes a first source/drain region, a second source/drain region disposed adjacent the first source/drain region and a nanosheet structure. The nanosheet structure includes a first channel region in contact with the first source/drain region, a second channel region in contact with the second source/drain region, a dielectric structure disposed between the first and second channel regions, a first sidewall feature disposed on a first side of the nanosheet structure, a second sidewall feature disposed on a second side of the nanosheet structure. The dielectric structure comprises a dielectric wall and a separation wall, the dielectric wall has a first surface facing the first channel region and a second surface facing the second channel region, and the separation wall is disposed within the dielectric wall. The first sidewall feature is disposed between the first and second source/drain regions and the first and second channel regions.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 11A, 11B, 12A-12D, 13, 14, 15, 16, 17, 18, 19, 20A, 20B, 21, 22, and 23 are cross-sectional views of intermediate stages in the manufacturing of nano-FETs, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments discussed herein are described in the context of a die including nano-FETs. However, various embodiments may be applied to dies including other types of transistors (e.g., fin field effect transistors (FinFETs), planar transistors, or the like) in lieu of or in combination with the nano-FETs.

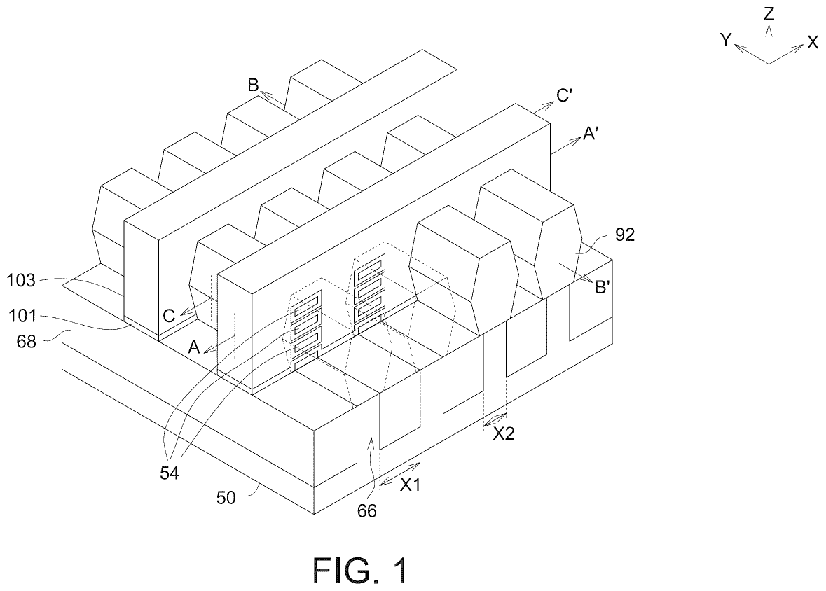

FIG. 1 illustrates an example of nano-FETs (e.g., nanowire FETs, nanosheet FETs, or the like) in a three-dimensional view, in accordance with some embodiments. The nano-FETs comprise nanostructures 54 (e.g., nanosheets, nanowire, or the like) over fins 66 on a substrate 50 (e.g., a semiconductor substrate), wherein the nanostructures 55 act as channel regions for the nano-FETs. The nanostructures 54 may include p-type nanostructures, n-type nanostructures, or a combination thereof. Shallow trench isolation (STI) regions 68 are disposed between adjacent fins 66, which may protrude above and form between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68.

Gate dielectric layers 101 extend along top surfaces and side surfaces of the fins 66 and along top surfaces, side surfaces, and bottom surfaces of the nanostructures 55. Gate electrode layers 103 are over the gate dielectric layers 101. Epitaxial source/drain regions 92 are disposed on the fins 66 on opposing sides of the gate dielectric layers 101 and the gate electrode layers 103.

FIG. 1 further illustrates reference cross-sections that are used in later figures. Cross-section A-A′ is along a longitudinal axis of a gate electrode layer 103 and in a direction, for example, perpendicular to the direction of current flow between the epitaxial source/drain regions 92 of a nano-FET. Cross-section C-C′ is parallel to cross-section A-A′ and extends through epitaxial source/drain regions 92 of multiple nano-FETs. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity.

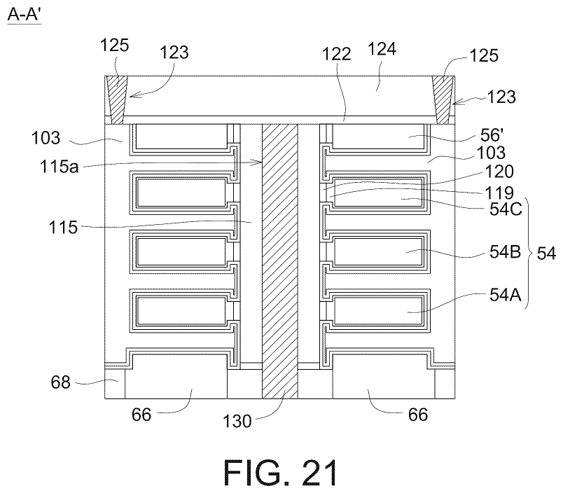

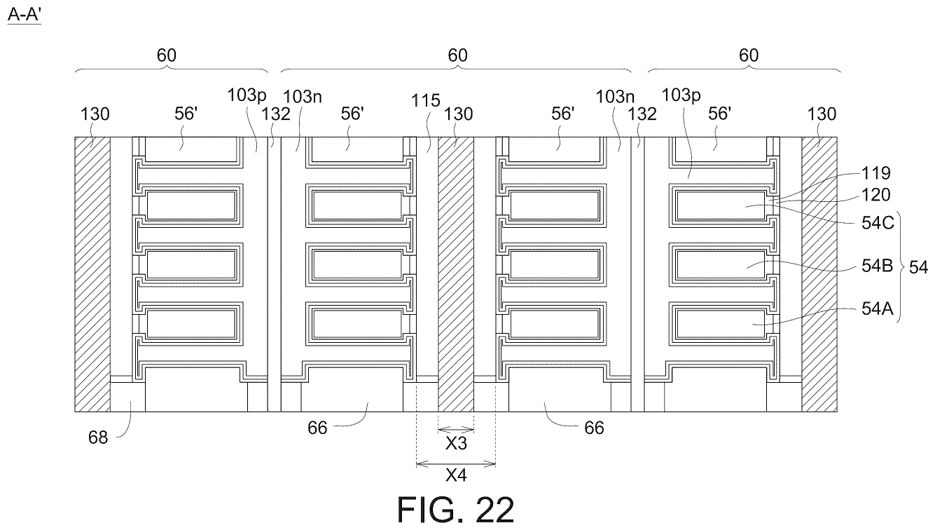

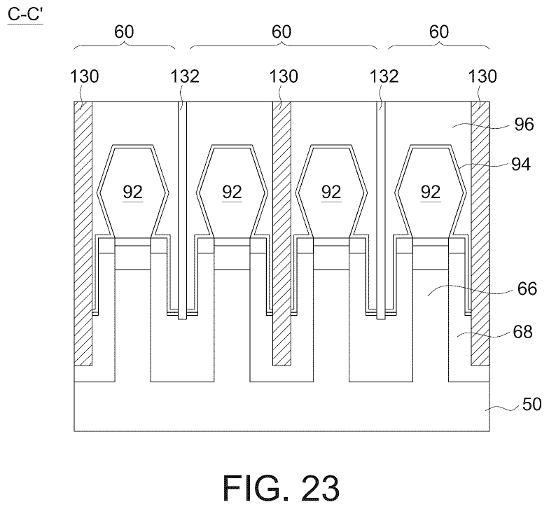

As shown in FIG. 1, the semiconductor device may include multiple fins 66 along the Y-axis, and multiple gate electrodes 103 along the X-axis. Dielectric walls 115 may be formed between neighboring fins 66 and within a gate electrode layer 103 to form a nanosheet structure. By forming the dielectric walls within the gate electrode layers 103, the semiconductor device reduces a fin distance X1 between two adjacent channel regions 55 along X-axis, which is defined as a distance of the gap between two neighboring fins 66, as illustrated in FIG. 1. In some embodiments, the fin distance X1 may be reduced for a percentage in a range between 25% and 35% due to dielectric walls described below. In some embodiments, the fin width X2 may be increased by 5% to 30% due to dielectric walls 115 (see FIGS. 21-22) and/or separation walls 130 (see FIG. 22-23) described below.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

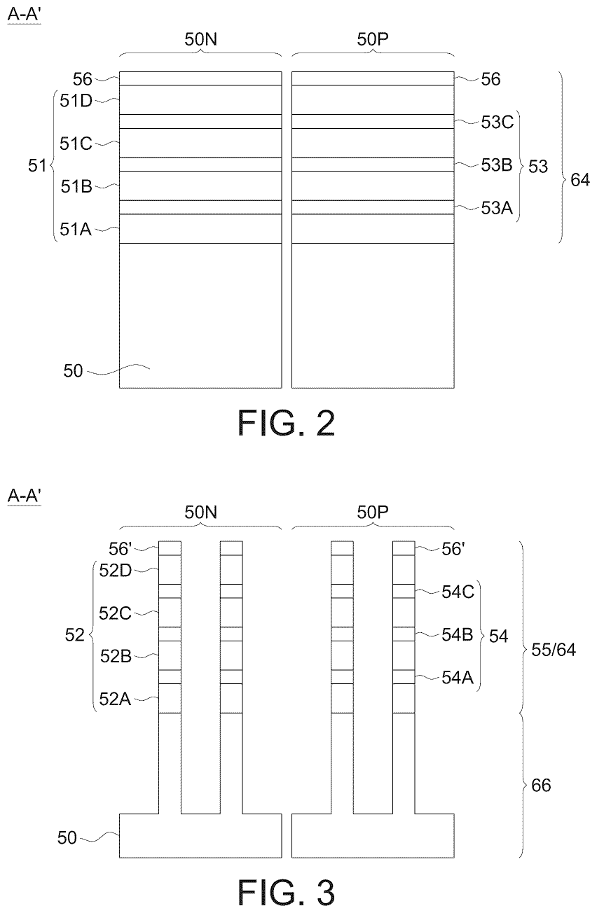

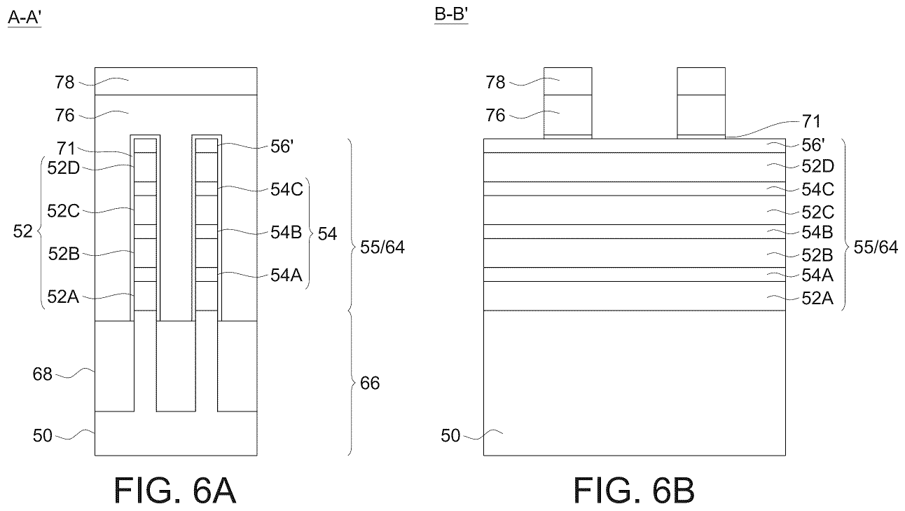

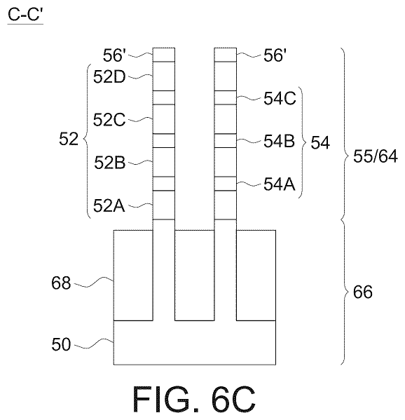

FIGS. 2 through 23 are cross-sectional views of intermediate stages in the manufacturing of nano-FETs, in accordance with some embodiments. FIGS. 2 through 5, 6A, 7A, 8A, 9A, 10A, 11A, 12A, 13, 14, 15, 16, 17, 18, 19, 20A, 20B, 21, and 22 illustrate reference cross-section A-A′ illustrated in FIG. 1. FIGS. 6B, 7B, 8B, 9B, 10B, 11B, and 12B illustrate reference cross-section B-B′ illustrated in FIG. 1. FIGS. 6C, 7C, 8C and 9C, 12C, 12D, and 23 illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by dividers, see FIG. 22), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53), and a protective layer 56 disposed on the uppermost second semiconductor layer 53C. For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material, such as silicon, silicon carbon, or the like. The multi-layer stack 64 is illustrated as having a bottommost semiconductor layer formed of the first semiconductor materials for illustrative purposes. In some embodiments, the multi-layer stack 64 may be formed such that the bottommost layer is formed of the second semiconductor materials.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

In FIG. 2, the protective layer 56 may be made of dielectric materials such as oxide, SiN, SiCON, SiCN or combinations thereof and may be formed by atomic layer deposition, pulsed plasma chemical vapor deposition, or any suitable deposition process.

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), a neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52, the second nanostructures 54 and the protective sheet 56′ may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than widths of the fins 66 in the p-type region 50P. Further, while each of the fins 66 and the nanostructures 55 are illustrated as having consistent widths throughout, in other embodiments, the fins 66 and/or the nanostructures 55 may have tapered sidewalls such that widths of the fins 66 and/or the nanostructures 55 continuously increases in a direction towards the substrate 50. In such embodiments, each of the nanostructures 55 may have different widths and be trapezoidal in shape.

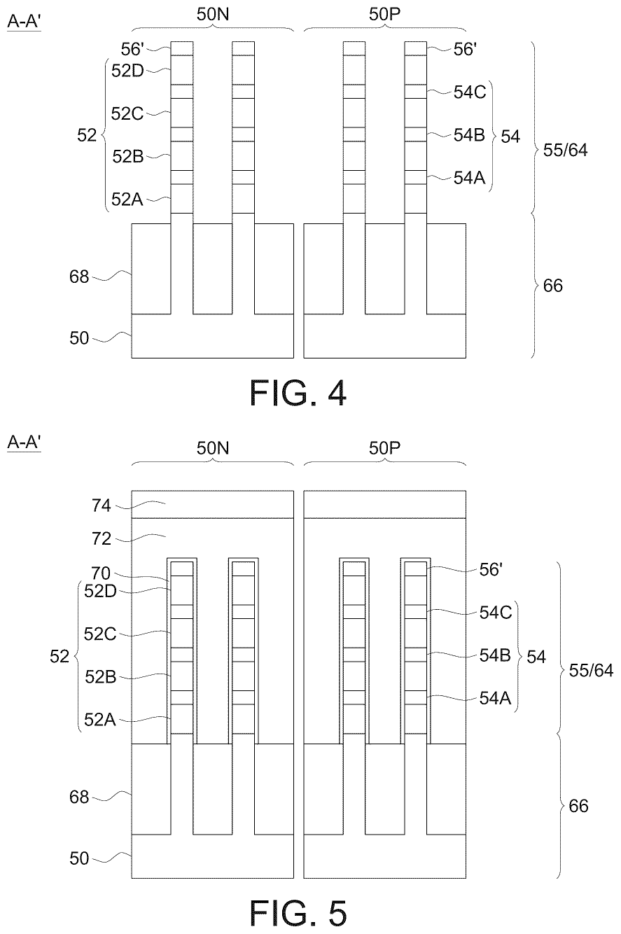

In FIG. 4, shallow trench isolation (STI) regions 68 are formed adjacent the fins 66. The STI regions 68 may be formed by depositing an insulation material over the substrate 50, the fins 66, and the nanostructures 55, and between adjacent ones of the fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along surfaces of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is completed.

The insulation material is then recessed to form the STI regions 68. The insulation material is recessed such that the nanostructures 55 and upper portions of fins 66 in the n-type region 50N and the p-type region 50P protrude from between neighboring STI regions 68. Further, the top surfaces of the STI regions 68 may have flat surfaces as illustrated, convex surfaces, concave surfaces (such as dishing), or combinations thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric acid (dHF) may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and the resulting first nanostructures 52) and the second semiconductor layers 53 (and the resulting second nanostructures 54) are illustrated and discussed herein as comprising the same materials in the p-type region 50P and the n-type region 50N for illustrative purposes only. In some embodiments, one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 23 illustrate various additional steps in the manufacturing of embodiment devices. FIGS. 6A through 23 illustrate features in either the n-type region 50N or the p-type region 50P. In FIGS. 6A through 6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66 and portions of the second nanostructures 54, which form channel regions. The pattern of the masks 78 may be used to separate each of the dummy gates 76 from adjacent dummy gates 76. The dummy gates 76 may have lengthwise directions perpendicular to lengthwise directions of respective ones of the fins 66.

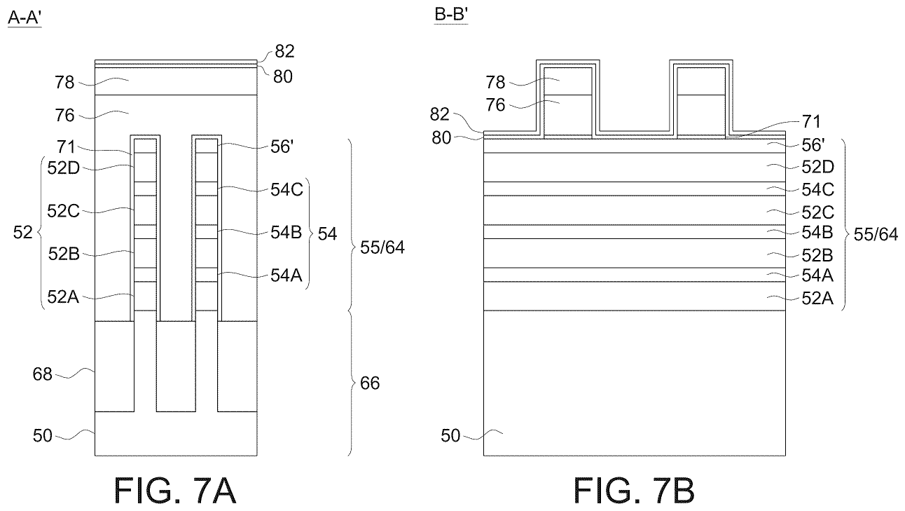

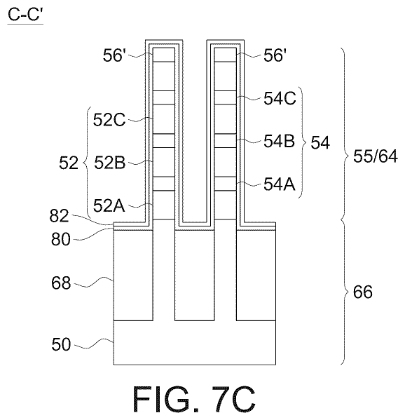

In FIGS. 7A through 7C, a first spacer layer 80 and a second spacer layer 82 are formed over the structures illustrated in FIGS. 6A through 6C. The first spacer layer 80 and the second spacer layer 82 will be subsequently patterned to act as spacers for forming self-aligned source/drain regions. In FIGS. 7A through 7C, the first spacer layer 80 is formed on top surfaces of the STI regions 68; side surfaces of the fins 66, the dummy gate dielectrics 71, and the dummy gates 76; and top surfaces and side surfaces of the nanostructures 55 and the masks 78. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like. The first spacer layer 80 and the second spacer layer 82 may comprise low-k dielectric materials.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and the exposed nanostructures 55 in the p-type region 50P. The mask may then be removed. Subsequently, a mask, such as a photoresist, may be formed over the p-type region 50P while exposing the n-type region 50N, and appropriate type (e.g., n-type) impurities may be implanted into the exposed fins 66 and the exposed nanostructures 55 in the n-type region 50N. The mask may then be removed. The n-type impurities may be the any of the n-type impurities previously discussed and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

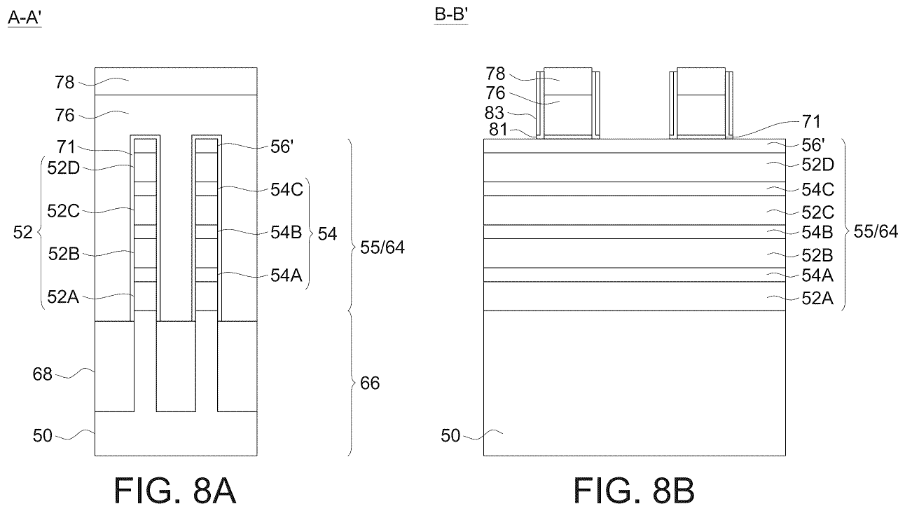

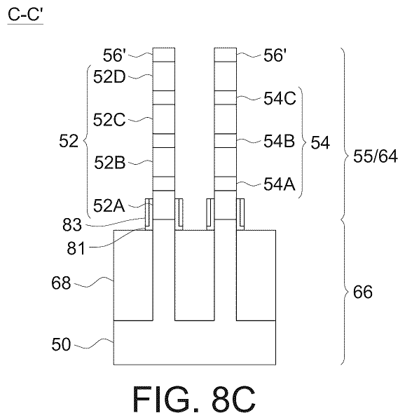

In FIGS. 8A through 8C, the first spacer layer 80 and the second spacer layer 82 are etched to form first spacers 81 and second spacers 83, respectively. As will be discussed in greater detail below, the first spacers 81 and the second spacers 83 act to self-align subsequently formed source/drain regions, as well as to protect sidewalls of the fins 66 and/or the nanostructures 55 during subsequent processing. The first spacer layer 80 and the second spacer layer 82 may be etched using suitable etching processes, such as isotropic etching processes (e.g., wet etching processes), anisotropic etching processes (e.g., dry etching processes), or the like. In some embodiments, the material of the second spacer layer 82 has a different etch rate than the material of the first spacer layer 80, such that the first spacer layer 80 may act as an etch stop layer when patterning the second spacer layer 82. The second spacer layer 82 may act as a mask when patterning the first spacer layer 80. For example, the second spacer layer 82 may be etched using an anisotropic etch process in which the first spacer layer 80 acts as an etch stop layer. Remaining portions of the second spacer layer 82 form the second spacers 83, as illustrated in FIGS. 8B and 8C. The second spacers 83 then act as a mask while etching exposed portions of the first spacer layer 80 forming the first spacers 81, as illustrated in FIGS. 8B and 8C.

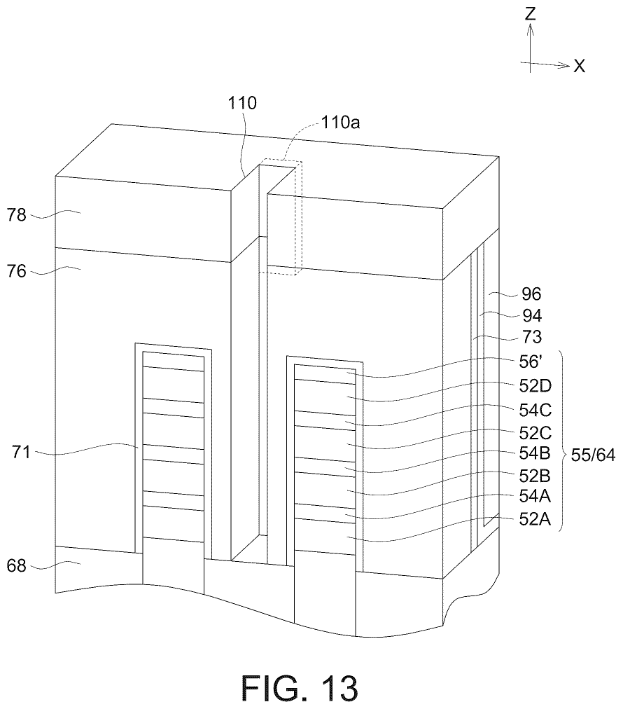

As illustrated in FIG. 8B, the first spacers 81 and the second spacers 83 are disposed on sidewalls of the masks 78, the dummy gates 76, and the dummy gate dielectrics 71. In some embodiments, top surfaces of the first spacers 81 and the second spacers 83 may be disposed below top surfaces of the masks 78. The top surfaces of the first spacers 81 and the second spacers 83 may be disposed level with or above the top surfaces of the masks 78. In some embodiments, the second spacers 83 may be removed from over the first spacers 81 adjacent the masks 78, the dummy gates 76, and the dummy gate dielectrics 71. As illustrated in FIG. 8C, the first spacers 81 and the second spacers 83 are disposed on sidewalls of the fins 66 and/or nanostructures 55. One set of the first spacers 81 and the second spacers 83 is called as a sidewall feature 73 in FIGS. 13-16 hereafter.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

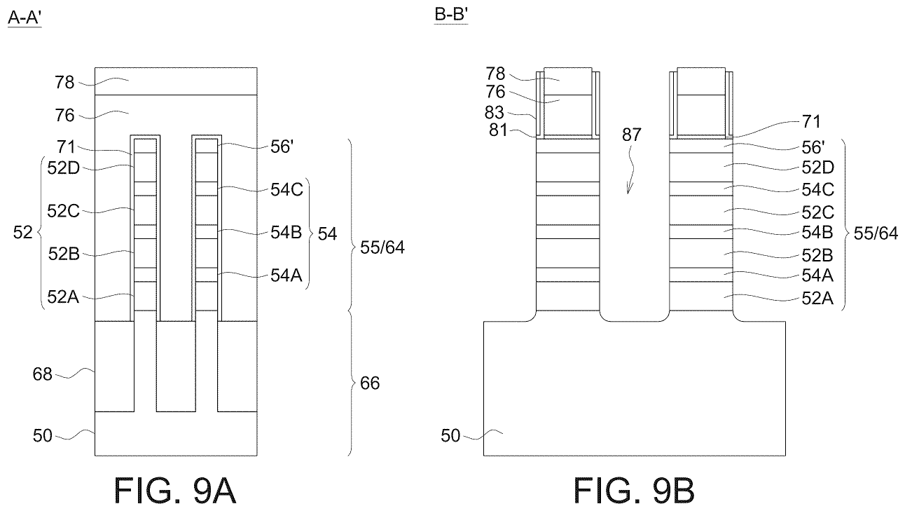

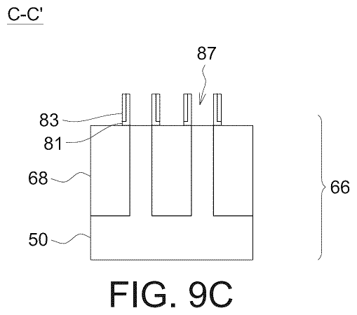

In FIGS. 9A through 9C, first recesses 87 are formed in the fins 66, the nanostructures 55, and the substrate 50. Epitaxial source/drain regions will be subsequently formed in the first recesses 87. The first recesses 87 may extend through the first nanostructures 52 and the second nanostructures 54, and into the substrate 50. In some embodiments, top surfaces of the STI regions 68 may be level with bottom surfaces of the first recesses 87. In some embodiments, the top surfaces of the STI regions 68 may be above or below the bottom surfaces of the first recesses 87. The first recesses 87 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 87. A single etch process or multiple etch processes may be used to etch each layer of the nanostructures 55 and/or the fins 66. Timed etch processes may be used to stop the etching after the first recesses 87 reach desired depths. The trench depth of the source/drain regions 92 can be controlled by the etching process. In one embodiment, the bottom of the first recesses 87 is, for example, slightly lower than the upper surface of the substrate 50 or deeper than the upper surface of the substrate 101.

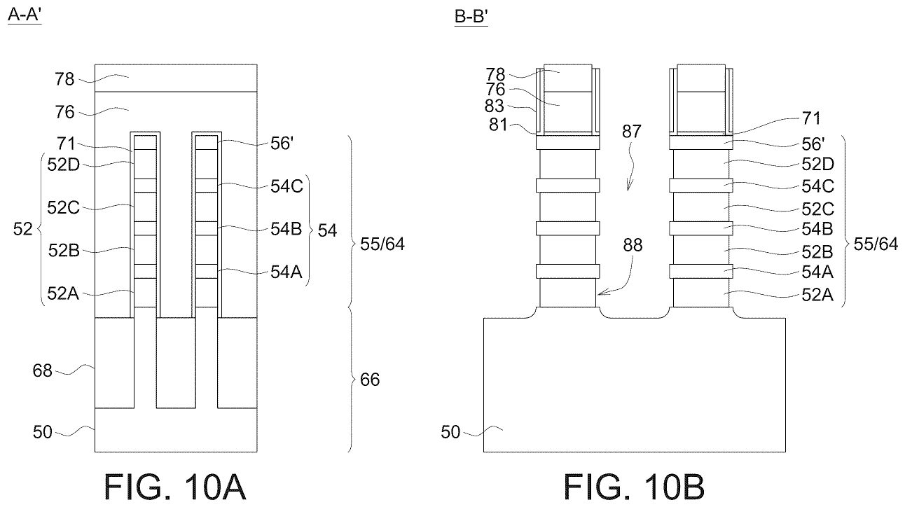

In FIGS. 10A and 10B, portions of sidewalls of the layers of the multi-layer stack 64 formed of the first semiconductor materials (e.g., the first nanostructures 52) exposed by the first recesses 87 are etched to form sidewall recesses 88. Although sidewalls of the sacrificial dielectric nanostructures 52A-52D adjacent the sidewall recesses 88 are illustrated as being straight in FIG. 10B, the sidewalls may be concave or convex. The sidewalls may be etched using isotropic etching processes, such as wet etching or the like. In an embodiment in which the first nanostructures 52A-52D include, e.g., SiGe, and the second nanostructures 54 include, e.g., Si or SiC, a dry etch process with tetramethylammonium hydroxide (TMAH), ammonium hydroxide (NH₄OH), or the like may be used to etch the first nanostructures 52A-52D.

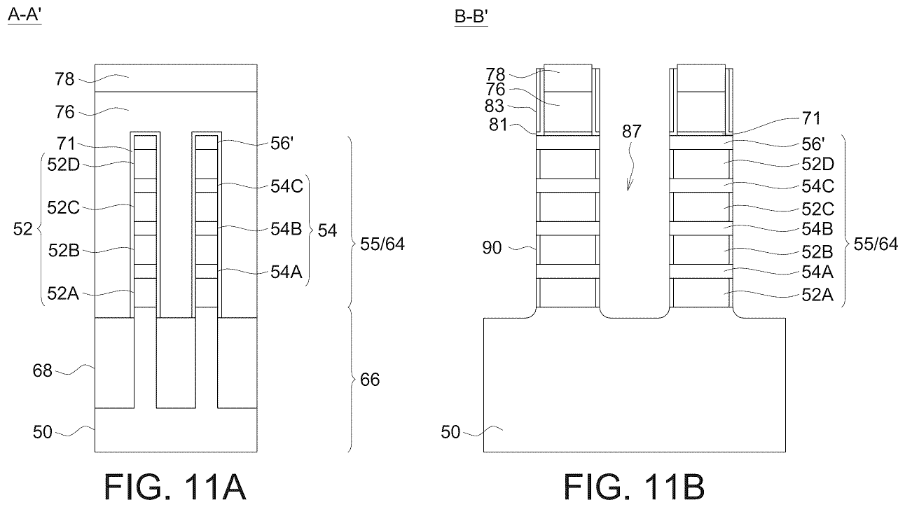

In FIGS. 11A through 11B, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and subsequently formed gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as flush with sidewalls of the second nanostructures 54, the outer sidewalls of the first inner spacers 90 may extend beyond or be recessed from sidewalls of the second nanostructures 54.

Moreover, although the outer sidewalls of the first inner spacers 90 are illustrated as straight in FIG. 11B, the outer sidewalls of the first inner spacers 90 may be concave or convex. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed with respect to FIG. 1) by subsequent etching processes, such as etching processes used to form gate structures.

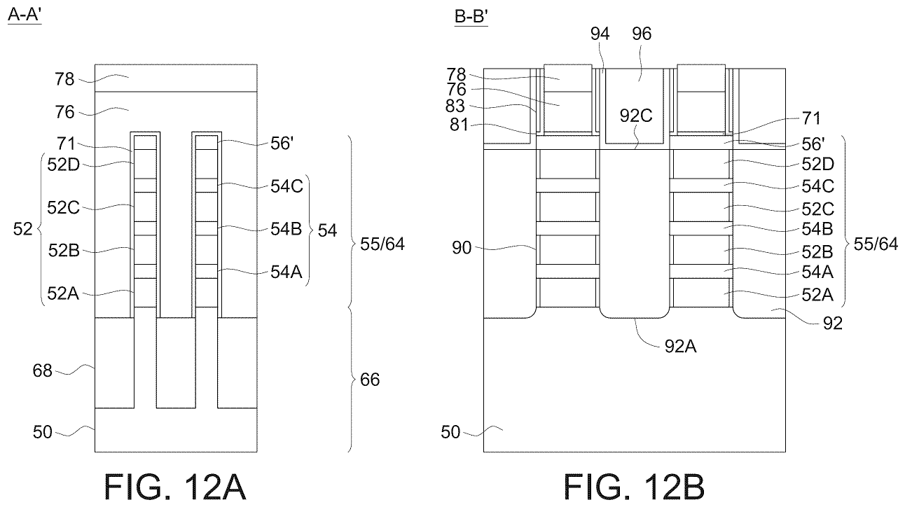

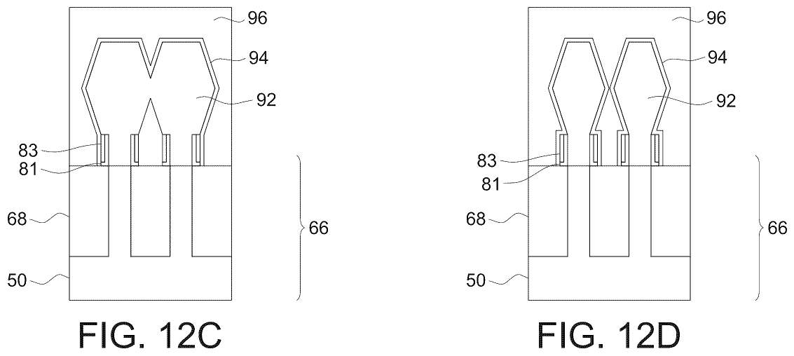

In FIGS. 12A through 12D, epitaxial source/drain regions 92 are formed in the first recesses 87. In some embodiments, the epitaxial source/drain regions 92 may exert stress on the second nanostructures 54, thereby improving performance. As illustrated in FIG. 12B, the epitaxial source/drain regions 92 are formed in the first recesses 87 such that each dummy gate 76 is disposed between respective neighboring pairs of the epitaxial source/drain regions 92. In some embodiments, the first spacers 81 and the second spacers 83 are used to separate the epitaxial source/drain regions 92 from the dummy gates 76 and the first inner spacers 90 are used to separate the epitaxial source/drain regions 92 from the first nanostructures 52 by appropriate lateral distances so that the epitaxial source/drain regions 92 do not short out subsequently formed gates of the resulting nano-FETs.

In FIG. 12B, the epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 87 of the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous-doped silicon carbide, silicon phosphide, or the like. The epitaxial source/drain regions 92 may have surfaces raised from respective upper surfaces of the second nanostructures 54 and may have facets.

The epitaxial source/drain regions 92 in the p-type region 50P, e.g., the PMOS region, may be formed by masking the n-type region 50 N, e.g., the NMOS region. Then, the epitaxial source/drain regions 92 are epitaxially grown in the recesses 87 of the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective upper surfaces of the second nanostructures 54 and may have facets.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, the facets cause adjacent epitaxial source/drain regions 92 of a same nano-FET to merge as illustrated by FIG. 12C. In some embodiments, adjacent epitaxial source/drain regions 92 remain separated after the epitaxy process is completed as illustrated by FIG. 12D. In the embodiments illustrated in FIGS. 12C and 12D, the first spacers 81 may be formed over top surfaces of the STI regions 68 and may block the epitaxial growth. In some embodiments, the first spacers 81 may cover portions of sidewalls of the second nanostructures 54 and the protective sheets 56′ also block the epitaxial growth beyond the uppermost second nanostructures 54C. In some embodiments, the spacer etch used to form the first spacers 81 may be adjusted to remove the spacer material to allow the epitaxial source/drain regions 92 to extend to the top surfaces of the STI regions 68.

The epitaxial source/drain regions 92 may comprise one or more semiconductor material layers. For example, the epitaxial source/drain regions 92 may comprise a first semiconductor material layer, a second semiconductor material layer, and a third semiconductor material layer. Any number of semiconductor material layers may be used for the epitaxial source/drain regions 92. Each of the first semiconductor material layer, the second semiconductor material layer, and the third semiconductor material layer may be formed of different semiconductor materials and may be doped to different dopant concentrations. In some embodiments, the first semiconductor material layer may have a dopant concentration less than the second semiconductor material layer and greater than the third semiconductor material layer. In embodiments in which the epitaxial source/drain regions 92 comprise three semiconductor material layers, the first semiconductor material layer may be deposited, the second semiconductor material layer may be deposited over the first semiconductor material layer, and the third semiconductor material layer may be deposited over the second semiconductor material layer.

The first and second spacers 81 and 83 may have a thickness in a range between about 4 nm and about 7 nm. In some embodiments, the insulating material of the first and second spacers 81 and 83 is a silicon nitride-based material, such as SiN, SiON, SiOCN or SiCN and combinations thereof. In addition, a contact etch stop layer (CESL) 94 and an interlayer dielectric (ILD) layer 96 are formed over the exposed surfaces, such as on the epitaxial source/drain regions 92, the sidewall features 73, and the STI region 68. In some embodiments, the CESL 94 has a thickness in a range between about 4 nm and about 7 nm. The CESL 94 may include Si₃N₄, SiON, SiCN or any other suitable material, and may be formed by CVD, PVD, or ALD. The interlayer dielectric (ILD) layer 96 is formed over the CESL 94. The ILD layer 96 protects the epitaxial source/drain regions 92 during the removal of the dummy gates 76.

In FIG. 13, the dummy gates 76 and the masks 78 are partially etched to form a recess 110 with high aperture ratio. The recess 110 extends along the vertical direction of the dummy gates 76 and the masks 78 and is formed between two adjacent nanostructures 55 in the dummy gates 76. In the Y-axis, the recess 110 terminates at the two sidewall features 73 on opposing sides of the dummy gates 76. That is, first one of the sidewall features 73 is disposed on first side of the dummy gate 76, and second one of the sidewall features 73 is disposed on second side of the dummy gate 76. In FIG. 13, although only one sidewall feature 73 located on one side of the dummy gate 76 is shown, it is known that another sidewall feature 73 is located on opposing side of the dummy gate 76.

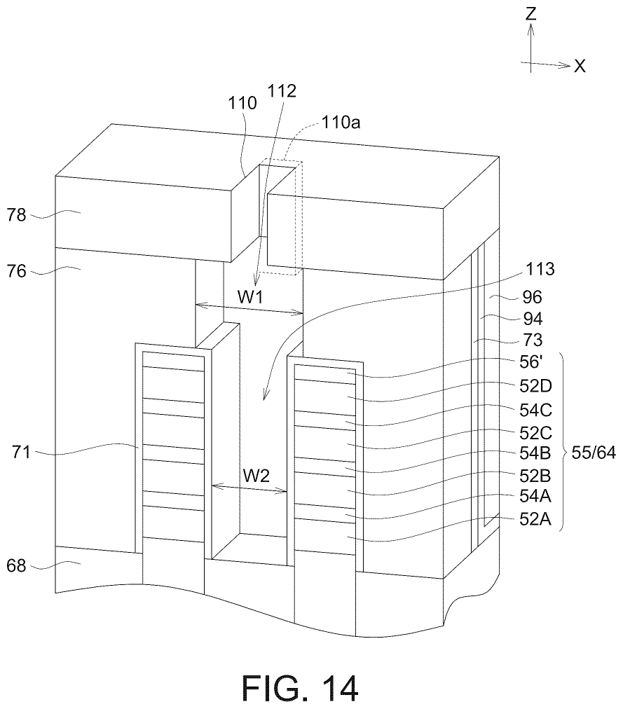

In FIG. 14, the dummy gates 76 are further etched to form a recess 110 with an enlarged opening 112 on the top of the nanostructures 55 and a narrow opening 113 between the nanostructures 55. The enlarged opening 112 has a first width W1 in the second direction (i.e. X-axis direction) and the narrow opening 113 on the bottom of the recess 110 has a second width W2 in the same direction. The second width W2 is less than the first width W1 so that a portion of the dummy gate dielectrics 71 on the top of the nanostructures 55 is exposed from the enlarged opening 112. In addition, another portion of the dummy gate dielectrics 71 on opposite sides of the nanostructures 55 is exposed from the narrow opening 113. In some embodiment, the first width W1 may be between 35 nm and 55 nm, and the first width W2 may be between 35 nm and 50 nm. The width of two adjacent fins 66 may be between 30 nm and 45 nm.

In FIG. 14, the sidewall features 73 and the CESL 94 may be selectively etched to form an opening 110a on the top of the sidewall features 73 and the CESL 94. In one embodiment, the opening 110a may be omitted if the sidewall features 73 and the CESL 94 have high etching selectivity relative to the dummy gates 76.

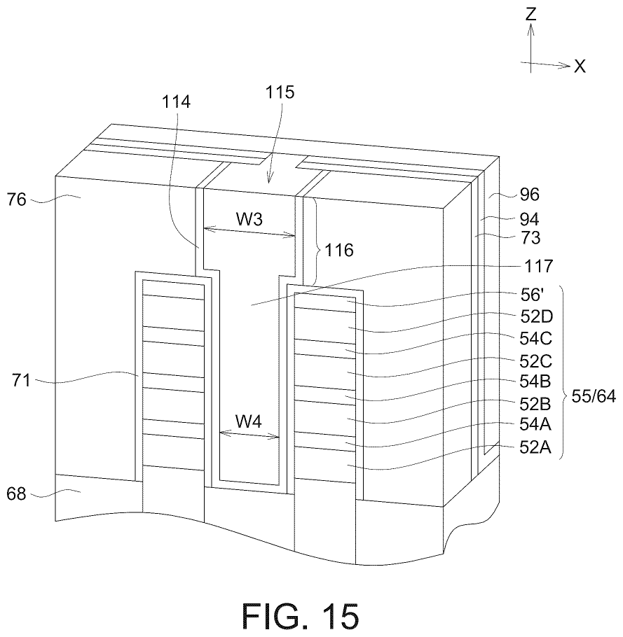

In FIG. 15, the masks 78 are removed and a liner 114 is formed in the recess 110. The liner 114 is deposited on the sidewalls and the bottom surface of the recess 110. That is, the liner 114 covers the exposed portion of the dummy gate dielectrics 71 and the dummy gates 76. In FIG. 15, a dielectric wall 115 is formed in the recess 110 after the liner 114 is formed. The dielectric wall 115 has an enlarged wall 116 corresponding to the enlarged opening 112 of the recess 110 and a narrow wall 117 corresponding to the narrow opening 113 of the recess 110. The width W3 of the enlarged wall 116 is greater than the width W4 of the narrow wall 117. The dielectric wall 115 is formed for separating from the two adjacent nanostructures 55 so that the parasitic capacitance induced by EPI/metal gate structure between the nanostructures 55 can be reduced. In some embodiment, the width W3 may be between 35 nm and 55 nm, and the width W4 may be between 35 nm and 50 nm. The width of two adjacent fins 66 may be between 30 nm and 45 nm.

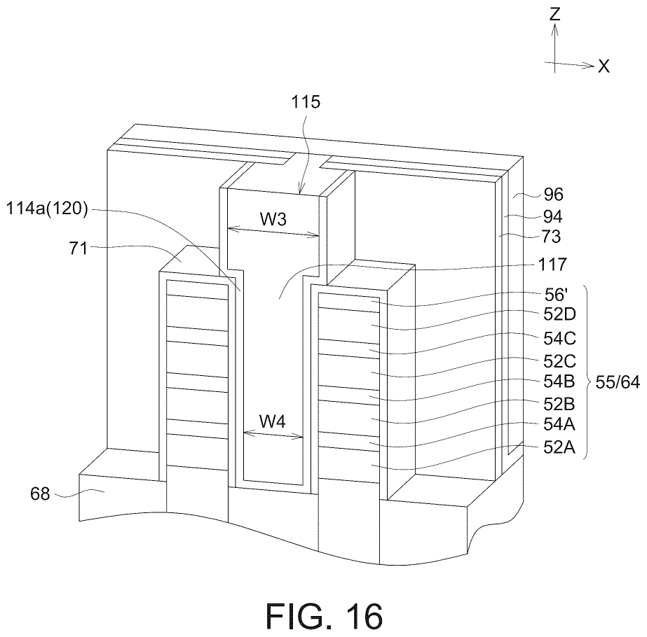

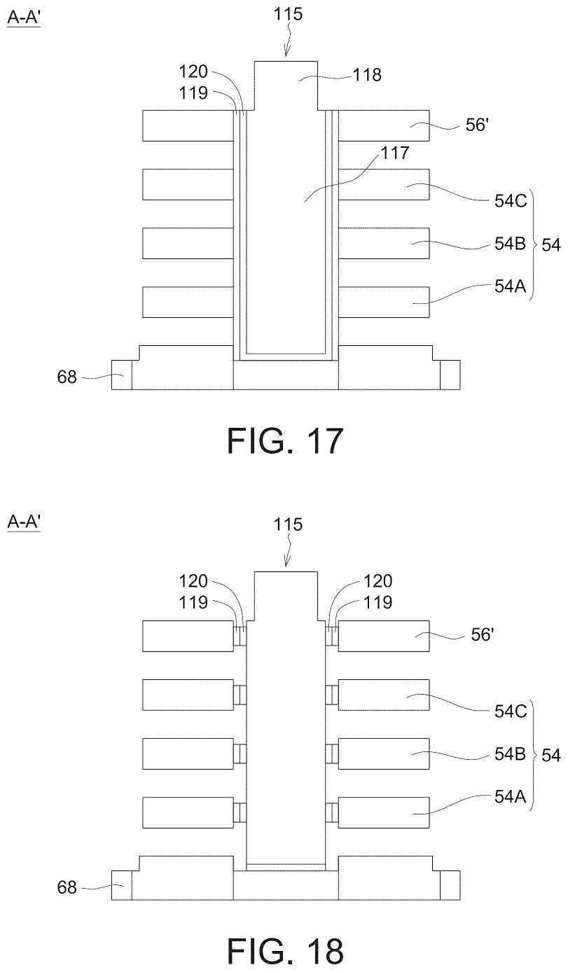

In FIG. 16, the dummy gates 76 are removed in one or more etching steps. Portions of the liner 114 and the dielectric wall 115 in the recess 110 are also be removed in FIGS. 17 and 18. In some embodiments, the dummy gates 76 are removed by an anisotropic dry etch process. For example, the etching process may include a dry etch process using reaction gas(es) that selectively etch the dummy gates 76 at a faster rate than the first spacers 81, the second spacers 83, the nanostructures 55, the STI regions 68 or the liner 114. During the removal of the dummy gates 76, the dummy gate dielectrics 71 may be used as etch stop layers. In FIG. 17, portions of the dummy gate dielectrics 71 and all of the sacrificial dielectric nanostructures 57A-57C may then be removed after the removal of the dummy gates 76, and portions of the liner 114 may be removed by an anisotropic dry etch process, while the un-etched portion 119 of the dummy gate dielectrics 71 and the un-etched liner 114 may remain to form two end caps in FIG. 18.

In FIG. 17, the sacrificial dielectric nanostructures 57A-57C may be removed by performing an isotropic etching process such as wet etching or the like using etchants selective to the materials of the first nanostructures 52, while the second nanostructures 54, the substrate 50, and the STI regions 68 remain relatively un-etched as compared to the first nanostructures 52.

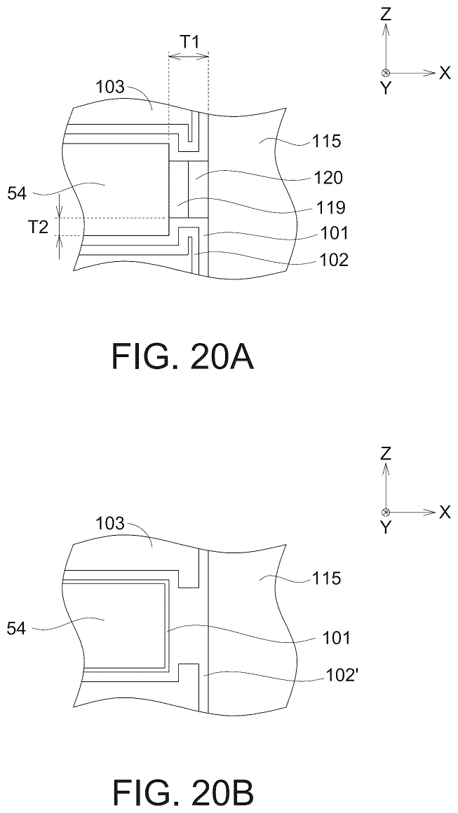

In FIG. 17, when the sacrificial dielectric nanostructures 57A-57C are removed, the dummy gate dielectrics 71 remains un-etched to form first end caps 119 on the sides of the second nanostructures 54, and the liner 114 remains un-etched to form second end caps 120 between the first end caps 119 and the dielectric wall 115. In some embodiments, the second end caps 120 may be a SiN layer and the first end caps 119 includes SiO₂. In some embodiments, the second end caps 120 may be used to define a gate end cap on a channel in a nanosheet structure. For example, a thickness T1 of the second end caps 120 on an end surface of the second nanostructures 54 may be used to define a thickness of the gate end cap. In some embodiments, the thickness T1 of the gate end cap may be in a range between about 0 nm and about 5 nm, the height T2 of the gate dielectric layers 101 may be in a range between about 0 nm and about 2 nm, as shown in FIG. 20A.

In FIGS. 20A and 20B, the first end caps 119 may be silicon oxide with a thickness of about 2-3 nm, and the second end caps 120 may be silicon nitride or silicon carbon nitride with a thickness of about 2-3 nm. Portions of the first and second end caps 119 and 120 are etched along the first etching direction along Z-axis and second etching direction along Y-axis so that the profile of the first and second end cap layers 119 and 120 may be concave shape. In FIG. 20A, the profile of the first and second end caps 119 and 120 may be arc-shaped, while the dielectric wall 115 remains un-etched to have a straight profile or an arc-shaped in the first and second etching directions along Z-axis and Y-axis. In some embodiments, the width of the first end caps 119 may be less than the width of the second end cap 120 to form a taper shape in the direction along X-axis.

In FIG. 20B, if the first end caps 119 and the second end caps 120 are removed completely, the second gate dielectric layers 102 of high-k dielectric material in FIG. 20A may merge at the gap to form a π-shaped gate dielectric layers 102′ around the second nanostructures 54. The π-shaped gate dielectric layers 102′ has a width about 0-5 nm between the second nanostructures 54 and the dielectric wall 115. In some embodiments, when more of the second end caps 120 is removed, the effective length of the subsequent gate structure increases, leading to improved gate control performance. When more of the second end caps 120 remains un-etched, the low-k dielectric material in the second end caps 120 improves average capacitance (AC) performance.

After formation of the dielectric wall 115, a replacement gate process may be performed to form gate structures on two sides of the dielectric wall 115. The replacement gate structure may include gate dielectric layers 100 and gate electrode layers 103 as shown in FIG. 1.

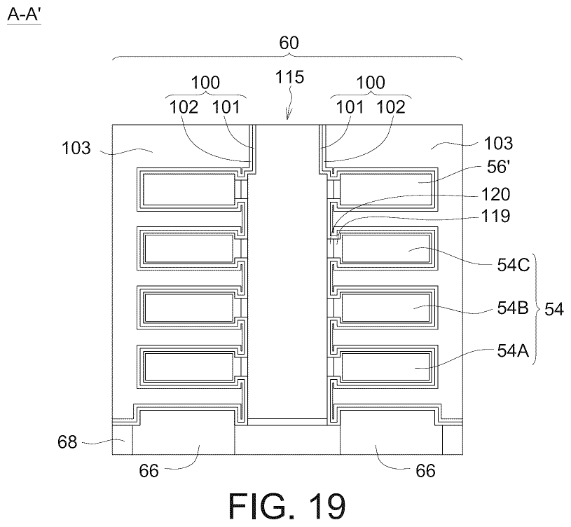

In FIG. 19, the gate dielectric layers 100 are deposited conformally in the spaces between the second nanostructures 54. The gate dielectric layers 100 may be formed on top surfaces and side surfaces of the fins 66 and on top surfaces, side surfaces, and bottom surfaces of the second nanostructures 54. The gate dielectric layers 100 may also be deposited on top surfaces of the second spacers 83, and the STI regions 68; on top surfaces and side surfaces of the first spacers 81; and on side surfaces of the first inner spacers 90 (shown in FIG. 11B). The gate dielectric layers 100 comprise one or more dielectric layers, such as an oxide, a metal oxide, the like, or combinations thereof. In some embodiments, the gate dielectric layers 100 may comprise first gate dielectric layers 101 (e.g., comprising silicon oxide or the like) and second gate dielectric layers 102 (e.g., comprising a metal oxide or the like) of high-k dielectric material. In some embodiments, the second gate dielectric layers 102 may have a k-value greater than about 7.0, and may include a metal oxide or a silicate of hafnium, alumium, zirconium, lanthanum, manganese, barium, titanium, lead, and combinations thereof. The first gate dielectric layers 101 may be referred to as interfacial layers, and the second gate dielectric layers 102 may be referred to as high-k gate dielectric layers, in some embodiments.

The structure of the gate dielectric layers 100 may be the same or different in the n-type region 50N and the p-type region 50P. For example, the p-type region 50P may be masked or exposed while forming the gate dielectric layers 100 in the n-type region 50N. In embodiments where the p-type region 50P is exposed, the gate dielectric layers 100 may be simultaneously formed in the p-type regions 50P. The formation methods of the gate dielectric layers 100 may include molecular-beam deposition (MBD), ALD, CVD, PVD, and the like.

In FIG. 19, gate electrode layers 103 formed over the gate dielectric layers 100. In FIG. 19, the gate electrode layers 103 are separated by the dielectric structure (i.e., dielectric wall). In some embodiments, the conductive materials may be gate electrodes having a π-shape in a cross-sectional view along the second direction (i.e., X-axis direction). The dielectric wall is disposed between two adjacent channel regions (i.e., second nanostructures 54) of a nanosheet structure 60.

The gate electrode layers 103 may fill the spaces between the second nanostructures 54 and extend over the gate dielectric layers 100. The gate electrode layers 103 may be deposited conformally by a process such as ALD, CVD, PVD, or the like. In some embodiments, the gate electrode layers 103 is a p-type work function layer and/or a n-type work function layer, which may comprise W, Cu, TiN, Ti, Pt, Ta, TaN, Co, Ni, TaC, TaCN, TaSiN, TaSi₂, NiSi₂, Mn, Zr, ZrSi₂, TaN, Ru, Mo, MoSi₂, WN, WCN, other metal oxides, metal nitrides, metal silicates, transition metal-oxides, transition metal-nitrides, transition metal-silicates, oxynitrides of metals, metal aluminates, zirconium silicate, zirconium aluminate, combination thereof, or the like. After filling of the gate electrode layers 103 over the second nanostructures 54, a planarization process, such as a CMP, may be performed to remove the excess portions of the gate electrode layers 103, which excess portions are over the top surface of the ILD layer 96, the first spacers 81, and the second spacers 83. In FIG. 21, a planarization process is performed to remove portions of the protective sheets 56′, and the height of the remaining protective sheets 56′, for example, increases by 1 nm to 8 nm so that the π-shaped gate electrode layers 103 have uniform thicknesses on the top and bottom of the second nanostructures 54.

In FIGS. 21 through 23, separation walls 130 may be formed in the dielectric wall 115 for separating adjacent epitaxial source/drain regions 92 (referring to FIG. 23) of a nanosheet structure 60. The nanosheet structure 60 can also be called as a forksheet structure. The dielectric wall 115 may be patterned using acceptable photolithography and etching techniques to form a third recess 115a passing through the dielectric wall 115 and the first ILD layer 96 covering the epitaxial source/drain regions 92, and then a separating material such as dielectrics may be filled into the third recess to form the epitaxy cut walls 130. As shown in FIG. 23, the separation walls 130 pass through the first ILD layer 96, the STI regions 68 to separate adjacent epitaxial source/drain regions 92. The separation walls 130 may have a thickness in a range between about 5 nm and about 20 nm. The separation walls 130 may enlarge the width of fins 66 about 1 nm to 6 nm for better current performance. The separation walls 130 may be single or multiple materials, such as oxide, SiN, SiCON, SiCN or combinations thereof. The separation walls 130 can also be called as cut epitaxy walls. Referring to FIG. 22, the width X3 of the separation walls 130 may be smaller than the width X4 of the dielectric wall 115 in the A-A′ section along X-axis direction.

In addition, cut gate structures 132 may be formed between n-type devices, such as NMOS transistors, e.g., n-type nano-FETs in the n-type regions, and p-type devices, such as PMOS transistors, e.g., p-type nano-FETs in the p-type regions. The cut gate structures 132 may separate adjacent first and second gate electrode layers 103n and 103p (referring to FIG. 22). The first and second gate electrode layers 103n and 103p are a p-type work function layer and/or an n-type work function layer, respectively.

The nanostructures 54 are disposed between the dielectric wall 115 having epitaxy cut walls 130 for the nanosheet structure and the cut gate structures 132. By limiting the dielectric wall 115 within the gate electrodes, the nanosheet structure of the present disclosure eliminates leakage concerns, reduces source/drain pitch, and increases volume of the source/drain region, thus improving device performance. Embodiments of the present disclosure also provides flexibility to gate profile adjustment, thus, adjust capacitance performance or control. Additionally, the dielectric wall of the present disclosure may be formed from a low-k material, thus, with improved capacitance performance.

In FIG. 21, a second ILD layer 124 is deposited over the CESL 122 by FCVD. In some embodiments, the second ILD layer 124 is formed of a dielectric material such as PSG, BSG, BPSG, USG, or the like, and may be deposited by any suitable method, such as CVD, PECVD, or the like. Portions of the second ILD layer 124 disposed above the first ILD layer 96 and the CESL 122 may be removed to form fourth recesses 123 exposing surfaces of the first and second gate electrode layers 103n and 103p. The fourth recesses 123 may be formed by etching using an anisotropic etching process, such as RIE, NBE, or the like. In some embodiments, the fourth recesses 123 may be etched through the second ILD layer 124 using a first etching process and may then be etched through the CESL 122 using a second etching process. In addition, gate contacts 125 are formed in the fourth recesses 123. The gate contacts 125 may each comprise one or more layers, such as barrier layers, diffusion layers, and fill materials. For example, in some embodiments, the gate contacts 125 each include a barrier layer and a conductive material over the barrier layer. The gate contacts 125 are each electrically coupled to underlying conductive features of the gate electrodes. The conductive material may be copper, a copper alloy, silver, gold, tungsten, cobalt, aluminum, nickel, or the like. A planarization process, such as a CMP, may be performed to remove excess material from surfaces of the second ILD layer 124 such that top surfaces of the gate contacts 125 are level with top surfaces of the second ILD layer 124.

The present disclosure is directed to improve the performance of the nano-FET. The dielectric structure is formed for separating two adjacent nanostructures from each other so that the parasitic capacitance induced by epitaxial/metal gate structure between the nanostructures can be reduced. In some embodiments, separation walls within the dielectric walls are disposed for separating two adjacent epitaxial source/drain regions from each other to reduce the source/drain pitch, increase fin width by 5% to 30% and volume of the epitaxial source/drain regions, thus improving device performance.

According to some embodiments, the present disclosure provides a semiconductor device comprising a first source/drain region, a second source/drain region disposed adjacent the first source/drain region and a nanosheet structure. The nanosheet structure includes a first channel region in contact with the first source/drain region, a second channel region in contact with the second source/drain region, a dielectric structure disposed between the first and second channel regions, a first sidewall feature disposed on a first side of the nanosheet structure, a second sidewall feature disposed on a second side of the nanosheet structure. The dielectric structure comprises a dielectric wall and a separation wall, the dielectric wall has a first surface facing the first channel region and a second surface facing the second channel region, and the separation wall is disposed within the dielectric wall. The first sidewall feature is disposed between the first and second source/drain regions and the first and second channel regions. The dielectric wall is disposed between the first sidewall feature and the second sidewall feature, and the separation wall passes through the first sidewall feature and the second sidewall feature for separating the first and second source/drain regions.

In some embodiments, the semiconductor device further comprises a first gate structure covering the first channel region, and the first gate structure is disposed at one side of the wall structure.

In some embodiments, the semiconductor device further comprises a second gate structure covering the second channel region, and the second gate structure is disposed at another side of the wall structure, wherein the first and second gate structures are separated by the wall structure.

In some embodiments, each of the first and second gate structures has a π-shape in a cross-sectional view.

In some embodiments, the first gate structure comprises an n-type work-function layer (i.e. the first conductive material 103n), and the second gate structure comprises a p-type work-function layer (i.e. the second conductive material 103p).

According to some embodiments, the present disclosure provides a semiconductor device comprising a first source/drain region, a second source/drain region disposed adjacent the first source/drain region and a nanosheet structure. The nanosheet structure includes a first channel region in contact with the first source/drain region, a second channel region in contact with the second source/drain region, a first protective sheet disposed on top of the first channel region, a second protective sheet disposed on top of the second channel region, a dielectric structure disposed between the first and second channel regions, a first sidewall feature and a second sidewall feature. The dielectric structure comprises a dielectric wall, the dielectric wall has a first surface facing the first channel region and a second surface facing the second channel region. The first sidewall feature is disposed between the first and second source/drain regions and the first and second channel regions. The first dielectric wall is disposed between the first sidewall feature and the second sidewall feature.

According to some embodiments, the present disclosure provides a method for manufacturing a semiconductor device, which comprises the following steps. A first source/drain region is formed over a semiconductor substrate. A second source/drain region is formed adjacent the first source/drain region. First and second sidewall features are formed on opposing sidewalls of a dummy gate structure, wherein the dummy gate structure covers across first nanostructures and second nanostructures. A recess is formed in the dummy gate structure between the first and second sidewall features. A dielectric structure is formed between the first and second nanostructures, wherein the dielectric structure comprises a dielectric wall in the recess. A separation wall is formed within the dielectric wall and passes through the first and second sidewall features, the separation wall is for separating the first and second source/drain regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first source/drain region;
a second source/drain region disposed adjacent the first source/drain region; and
a nanosheet structure comprising:
a first channel region in contact with the first source/drain region;
a second channel region in contact with the second source/drain region;
a dielectric structure disposed between the first and second channel regions, wherein the dielectric structure comprises a dielectric wall and a separation wall, the dielectric wall has a first surface facing the first channel region and a second surface facing the second channel region, and the separation wall is disposed within the dielectric wall;
a first sidewall feature disposed on a first side of the nanosheet structure, wherein the first sidewall feature is disposed between the first and second source/drain regions; and
a second sidewall feature disposed on a second side of the nanosheet structure, wherein the dielectric wall is disposed between the first sidewall feature and the second sidewall feature, and the separation wall passes through the first sidewall feature and the second sidewall feature for separating the first and second source/drain regions.

2. The semiconductor device according to claim 1, further comprising a first gate electrode layer covering the first channel region, and a second gate electrode layer covering the second channel region, wherein the first and second gate electrode layers are separated by the dielectric wall.

3. The semiconductor device according to claim 2, wherein each of the first and second gate electrode layers has a π-shape in a cross-sectional view.

4. The semiconductor device according to claim 3, wherein the first gate electrode layer comprises an n-type work-function layer, and the second gate electrode layer comprises a p-type work-function layer.

5. The semiconductor device according to claim 1, wherein a width of the separation wall is smaller than a width of the dielectric wall.

6. The semiconductor device according to claim 1, wherein the dielectric structure further comprises a first end cap and a second end cap on the first and second surfaces, wherein the first end cap is disposed between the first/second channel region and the second end cap, and the second end cap is disposed between the first end cap and the dielectric wall.

7. The semiconductor device according to claim 1, further comprising a cut gate structure extending along the separation wall, wherein the cut gate structure and the separation wall are disposed on opposing sides of the first channel region.

8. A semiconductor device comprising:
a first source/drain region;
a second source/drain region disposed adjacent the first source/drain region; and
a nanosheet structure comprising:
a first channel region in contact with the first source/drain region;
a second channel region in contact with the second source/drain region;
a first protective sheet disposed on top of the first channel region;
a second protective sheet disposed on top of the second channel region;
a dielectric structure disposed between the first and second channel regions, wherein the dielectric structure comprises a dielectric wall, the dielectric wall has a first surface facing the first channel region and a second surface facing the second channel region;
a first sidewall feature disposed on a first side of the nanosheet structure, wherein the first sidewall feature is disposed between the first and second source/drain regions; and
a second sidewall feature disposed on a second side of the nanosheet structure, wherein the first dielectric wall is disposed between the first sidewall feature and the second sidewall feature.

9. The semiconductor device according to claim 8, further comprising a first gate electrode layer covering the first channel region and the first protective sheet, and the first gate electrode layer is disposed at one side of the dielectric wall.

10. The semiconductor device according to claim 9, further comprising a second gate electrode layer covering the second channel region and the second protective sheet, and the second gate electrode layer is disposed at another side of the dielectric wall, wherein the first and second gate structures are separated by the dielectric wall.

11. The semiconductor device according to claim 10, wherein each of the first and second gate electrode layers has a π-shape in a cross-sectional view.

12. The semiconductor device according to claim 10, wherein the first gate electrode layer comprises an n-type work-function layer, and the second gate electrode layer comprises a p-type work-function layer.

13. The semiconductor device according to claim 8, wherein the dielectric structure further comprises a first end cap and a second end cap on the first and second surfaces, wherein the first end cap is disposed between the first/second channel region and the second end cap, and the second end cap is disposed between the first end cap and the dielectric wall.

14. The semiconductor device according to claim 8, the nanosheet structure further comprises a separation wall disposed within the dielectric wall and passing through the first sidewall feature and the second sidewall feature for separating the first and second source/drain regions.

15. The semiconductor device according to claim 14, further comprising:
a cut gate structure extending along the separation wall, wherein the cut gate structure and the separation wall are disposed on opposing sides of the first channel region or the second channel region.

16. A method for manufacturing a semiconductor device comprising:
forming a first source/drain region over a semiconductor substrate;
forming a second source/drain region adjacent the first source/drain region;
foming a first channel region in contact with the first source/drain region;
forming a second channel region in contact with the second source/drain region;
forming a first sidewall feature and a second sidewall feature between the first and second channel regions;
forming a dummy gate between the first and second sidewall features;
forming a recess in the dummy gate;
forming a dielectric structure between the first and second channel regions, wherein the dielectric structure comprises a dielectric wall in the recess; and
forming a separation wall within the dielectric wall and passing through the first and second sidewall features, the separation wall is for separating the first and second source/drain regions.

17. The method according to claim 16, wherein forming the dummy gate comprises:
depositing a dummy dielectric layer;
depositing a dummy gate layer over the dummy dielectric layer; and
patterning the dummy gate layer and the dummy dielectric layer to form the dummy gate, wherein the recess is formed through the dummy gate layer, and the dummy dielectric layer is exposed in the recess.
forming a liner in the recess to cover the sidewalls of the recess; and
forming the dielectric wall over the liner, wherein the liner separates the dummy dielectric layer from the dielectric wall.

18. The method according to claim 17, wherein forming the dielectric structure further comprises:
removing the dummy gate layer to expose a portion of the liner deposited on top of the dielectric wall and a portion of the dummy dielectric layer around the first and second regions; and
removing the portion of the dummy dielectric layer and the portion of the liner, and remaining un-etched portions of the dummy dielectric layer and the liner to form at least two end caps, wherein the two end caps are disposed on opposite sides of the dielectric wall and connected to the first and the second channel regions, respectively.

19. The method according to claim 18, wherein each of the two end caps comprises a first end cap and a second end cap, wherein the first end cap is disposed between the first/second channel regions and the second end cap, and the second end cap is disposed between the first end cap and the dielectric wall.

20. The method according to claim 18, further comprising:
forming a first gate electrode layer to cover the first channel regions, wherein the first gate structure is disposed at one side of the dielectric wall; and
forming a second gate electrode layer to cover the second channel regions, wherein the second gate structure is disposed at another side of the dielectric wall, and the first and second gate electrode layers are separated by the dielectric wall.
